(19) United States
(12) Patent Application Publication
(10) Pub. No.: US 2009/0309134 A1
(43) Pub. Date: Dec. 17, 2009

(54) SEMICONDUCTOR DEVICE AND METHOD OF MANUFACTURING THE SAME

(75) Inventors: Akihiko Nishio, Toyama (JP); Yoshiaki Shimada, Toyama (JP); Yoshiaki Kato, Toyama (JP); Yoshiharu Anda, Osaka (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Osaka (JP)

(21) Appl. No.: 12/423,347

(22) Filed: Apr. 14, 2009

(30) Foreign Application Priority Data
Jun. 11, 2008 (JP) 2008-152477

(51) Int. Cl. H01L 29/812; H01L 21/335

(52) U.S. Cl. 257/192; 438/172; 257/E29.317; 257/E21.403

(57) ABSTRACT

A multilayer structure including a first electron supply layer and a second electron supply layer is used for an electron supply layer. A multilayer structure including an SiN film and an SiO₂ film is used for an insulating film to be formed on the surface of a semiconductor. In forming an opening for exposing the electron supply layer in the insulating film, the SiN film that is in contact with the semiconductor is side-etched. Accordingly, it is possible to avoid a contact between a gate electrode and a portion, which is located on the side of the electron supply layer, of the inner peripheral surface of the opening, and further to expose only the second electron supply layer in the vicinity of the gate electrode.

### BACKGROUND OF THE INVENTION

1. Field of the Invention

The present invention relates to a semiconductor device and a method of manufacturing the semiconductor device.

2. Related Background Art

Conventionally, field-effect transistors (hereinafter referred to as “FETs”) using compound semiconductors such as GaAs are known as semiconductor devices. Such FETs are used widely in radio communication, in particular, power amplifiers and RF switches in mobile phone terminals, etc. Among these FETs, pseudomorphic high electron mobility transistors (PHEMTs) have especially excellent high-frequency characteristics. These PHEMTs also are used widely in semiconductor devices such as a monolithic microwave integrated circuit (MMIC) in which active elements such as an FET and passive elements such as a semiconductor resistor, a metal resistance element and a capacitor are integrated.

Not only PHEMTs used in MMICs but also FETs in general are required to reduce a leakage current. FIG. 6 shows a typical FET having a T-type gate structure utilizing a Schottky barrier. In this FET, an opening 12a is formed in an insulating film 12 formed on a semiconductor substrate 11, and a gate electrode 13 forms a Schottky junction with the semiconductor substrate 11 through the opening 12a.

The FET shown in FIG. 6, however, has the following problem. In this FET, the gate electrode 13 is in contact with the inner peripheral surface of the opening 12a even in the vicinity of the surface of the semiconductor substrate 11. Accordingly, strain is concentrated on a portion of the semiconductor substrate 11 directly below the inner peripheral surface of the opening 12a, and the electric field is enhanced locally in this portion. As a result, the reverse breakdown voltage of the Schottky junction drops, which causes a decrease in the output voltage in the RF characteristics or an increase in the leakage current.

JP 06(1994)-177163 A discloses, as a countermeasure against this problem, a manufacture of an FET by a method as shown in FIGS. 7A to 7D. This manufacturing method is specifically described below. First, as shown in FIG. 7A, the insulating film 12 is formed by stacking an SiN film 12a having a relatively high etching rate for wet etching and an SiN film 12b having a relatively low etching rate for wet etching, in this order, on the semiconductor substrate 11. The etching rates of the SiN films 12a and 12b are adjusted by controlling the film-forming conditions in a P-CVD process. Next, an SiO₂ film 15 serving as a spacer is formed on the insulating film 12. Subsequently, as shown in FIG. 7B, a patterned resist 16 is formed on the SiO₂ film 15 to define an opening region, and wet etching is performed using hydrofluoric acid. As a result, by utilizing the difference in the etching rate between the SiN films 12a and 12b of the insulating film 12, an opening 120 having an inner peripheral surface including two portions that have been side-etched in different amounts, that is, an upper portion 122 and a lower portion 121 that is located on the side of the semiconductor substrate 11 and recessed from the upper portion 122, is formed in the insulating film 12. After the wet etching is performed, as shown in FIG. 7C, a metal is evaporated on the semiconductor substrate 11 from above the resist 16 to form the gate electrode 13, and then the metal film 130 deposited on the resist 16 is lifted off. Thereby, an FET as shown in FIG. 7D is obtained, in which the gate electrode 13 is not in contact with the lower portion 121, which is located on the side of the semiconductor substrate 11, of the inner peripheral surface of the opening 120.

In a PHEMT, an AlGaAs layer commonly is used as a Schottky layer, and it is generally known that an AlGaAs layer has a high surface state density. Assume the case where the manufacturing method disclosed in JP 06(1994)-177163 A is applied to the manufacture of such a T-type gate PHEMT using an AlGaAs layer as a Schottky layer in order to avoid a contact between a gate electrode and a lower portion, which is located on the side of the AlGaAs layer, of the inner peripheral surface of an opening. In this case, a portion of the AlGaAs layer is exposed, and thus AlGaAs is naturally oxidized so that the formation of surface states is accelerated, which causes a problem such as a deterioration of high frequency response characteristics.

Furthermore, in an MMIC, the opening size for the gate corresponds to the gate length, but it is difficult to form gates having lengths as short as 0.5 μm or less with high consistency when the openings are formed in the insulating film by wet etching. A reduction in the gate length is an essential requirement for the high speed operation of the MMIC, and therefore, the manufacturing method using wet etching disclosed in JP 06(1994)-177163 A is not suitable for the manufacture of a PHEMT capable of achieving the high speed operation of the MMIC.

Furthermore, in the FET manufactured by the manufacturing method disclosed in JP 06(1994)-177163 A, the entire insulating film located between the head portion of the T-type gate electrode and the semiconductor substrate is composed of SiN, which is a common capacitor film. Therefore, when the FET is used in an MMIC, a loss is generated in the capacitance between the electrode and the semiconductor substrate.

### SUMMARY OF THE INVENTION

The present invention has been made in order to solve the above-mentioned problems, and it is an object of the present invention to provide a semiconductor device capable of reducing the leakage current without deteriorating the high frequency response characteristics and of reducing the gate length, and a method of manufacturing such a semiconductor device.

In order to a reduce a leakage current in a T-type gate PHEMT, it is necessary to avoid a contact between a gate electrode and a lower portion, which is located on the side of a Schottky layer, of the inner peripheral surface of an opening in an insulating film. However, in the PHEMT manufactured by the above-mentioned manufacturing method disclosed in JP 06(1994)-177163 A, the exposure of an AlGaAs layer as a Schottky layer causes the formation of surface states. Therefore, such a PHEMT is not suitable for the use in a MMIC. Accordingly, in one aspect of the present invention, an electron supply layer is formed by covering an AlGaAs layer with an InGaP layer having not only a lower surface state density and a better high frequency response but also a higher resistance to oxidation than the AlGaAs layer. However, since a PHEMT using a Schottky layer consisting of a single InGaP layer has a lower breakdown voltage and tends to increase a leakage current, compared with a PHEMT using a Schottky layer including an AlGaAs layer, it is preferable to form an InGaP layer with a thickness of 5 nm or less on the AlGaAs layer.

In the T-type gate PHEMT structured as described above, the leakage current can be reduced without deteriorating the high frequency response characteristics, even if the electron supply layer is exposed in the vicinity of the gate electrode.

In order to form, with high consistency, short gates capable of achieving the high speed operation in the MMIC, microfabrication by dry etching is required. In order to form, by dry etching, an opening having a shape adapted to avoid a contact between the gate electrode and the lower portion, which is located on the side of the electron supply layer, of the inner peripheral surface of the opening, it is preferable that the insulating film has a multilayer structure including an SiO₂ film and an SiN film. By utilizing the difference in the etching rate between the SiO₂ film and the SiN film, dry etching allows the SiN film to be side-etched with over-etching. It is preferable to perform this dry etching using an ICP dry etching apparatus and a mixed gas of CHF₃ and SF₆.

After the opening for the gate is formed in the insulating film by the above-mentioned dry etching technique and the photoresist is removed, a gate electrode material is deposited to form a film by a normal evaporation method, or a technique such as a long-throw sputtering method and a collimate sputtering method exhibiting excellent performance in the deposition in the normal line direction. Thus, it is possible to avoid a contact between the gate electrode and the lower portion, which is located on the side of the electron supply layer, of the inner peripheral surface of the opening for the gate.

After the gate electrode material is deposited to form a film, a patterned photoresist is formed on the film to define an opening region, and etching is performed. Thus, it is possible to form a T-type gate electrode. In this T-type gate structure, since the insulating film located between the head portion of the T-type gate electrode and the electron supply layer has a multilayer structure including an SiN film and an SiO₂ film, it has a low dielectric constant and thus a loss in the capacitance can be reduced.

In view of the above, the present invention provides a semiconductor device including: a channel layer formed on a semi-insulating substrate; an electron supply layer formed on the channel layer; an insulating film formed on the electron supply layer and having an opening for exposing the electron supply layer; and a gate electrode extending from above the insulating film to the electron supply layer through the opening, and forming, at its end, a Schottky junction with the electron supply layer. In this semiconductor device, the electron supply layer includes: a first electron supply layer disposed on the channel layer; and a second electron supply layer disposed on the first electron supply layer and having a lower surface state density and a higher resistance to oxidation than the first electron supply layer. The insulating film includes: an SiN film disposed on the electron supply layer; and an SiO₂ film disposed on the SiN film, and the SiN film and the SiO₂ film respectively have inner peripheral portions that constitute an inner peripheral surface of the opening. The inner peripheral portion of the SiO₂ film is in contact with the gate electrode, and the inner peripheral portion of the SiN film is recessed from the inner peripheral portion of the SiO₂ film to avoid a contact with the gate electrode.

The present invention also provides a method of manufacturing a semiconductor device. This manufacturing method includes: a first step of forming a channel layer on a semi-insulating substrate; a second step of forming an electron supply layer on the channel layer by stacking a first electron supply layer and a second electron supply layer in this order on the channel layer, the second electron supply layer having a lower surface state density and a higher resistance to oxidation than the first electron supply layer; a third step of forming an insulating film on the electron supply layer by stacking an SiN film and an SiO₂ film in this order on the electron supply layer; a fourth step of forming, in the insulating film, an opening for exposing the electron supply layer by dry etching; a fifth step of forming, through the opening, a Schottky junction between the electron supply layer and a metal film by depositing the metal film from above the insulating film to form the gate electrode; and a sixth step of forming the gate electrode by removing a portion of the metal film deposited outside the periphery of the opening on the insulating film.

According to the present invention, it is possible to obtain a semiconductor device having a low leakage current and excellent high frequency response characteristics, and further capable of high-speed operation.

### BRIEF DESCRIPTION OF THE DRAWINGS

FIG. 1 is a cross-sectional view of a semiconductor device according to a first embodiment of the present invention.

FIGS. 2A to 2C are diagrams for explaining a method of manufacturing the semiconductor device shown in FIG. 1.

FIGS. 3A to 3C are diagrams for explaining the method of manufacturing the semiconductor device shown in FIG. 1.

FIG. 4A is a cross-sectional view of a semiconductor device according to a second embodiment of the present invention, and FIG. 4B is a diagram for explaining a method of manufacturing the semiconductor device.

FIG. 5A is a cross-sectional view of a semiconductor device according to a third embodiment of the present invention, and FIG. 5B is a diagram for explaining a method of manufacturing the semiconductor device.

FIG. 6 is a cross-sectional view of a conventional semiconductor device.

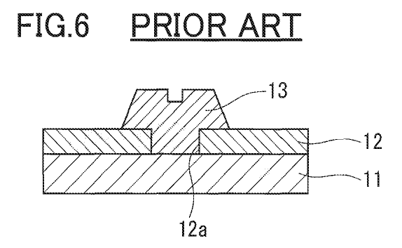

FIG. 7 is a diagram for explaining a method of manufacturing the conventional semiconductor device.

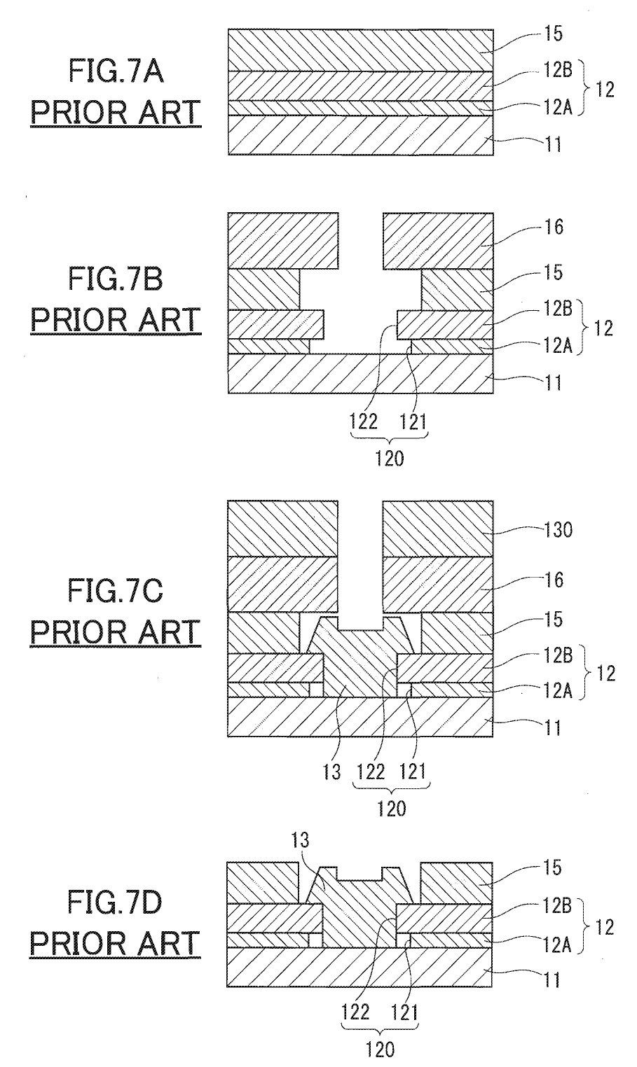

### DETAILED DESCRIPTION OF THE INVENTION

Hereafter, embodiments of the present invention will be described with reference to the accompanying drawings.

### First Embodiment

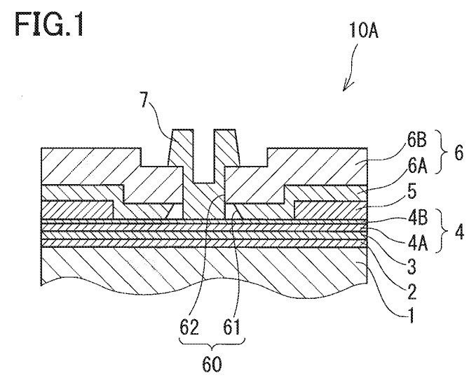

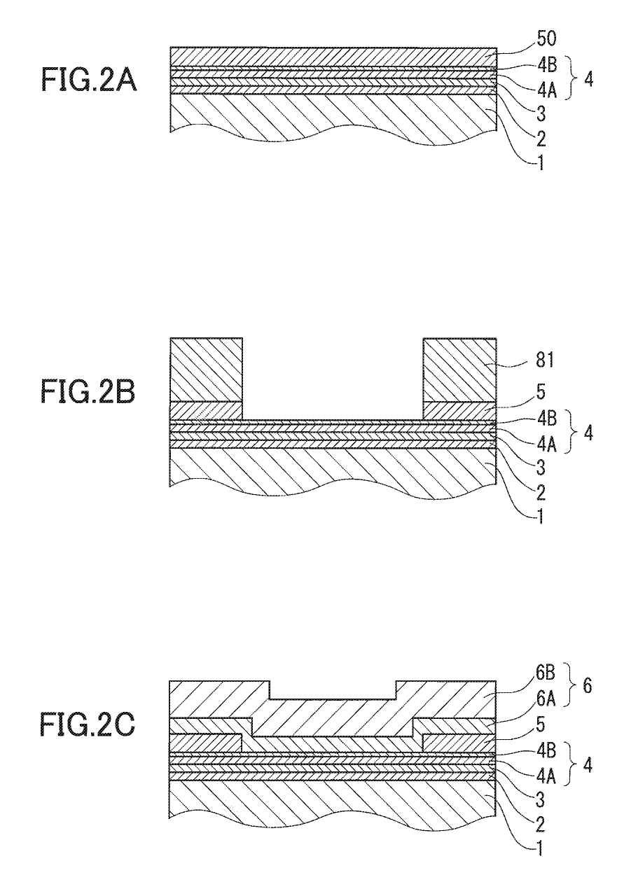

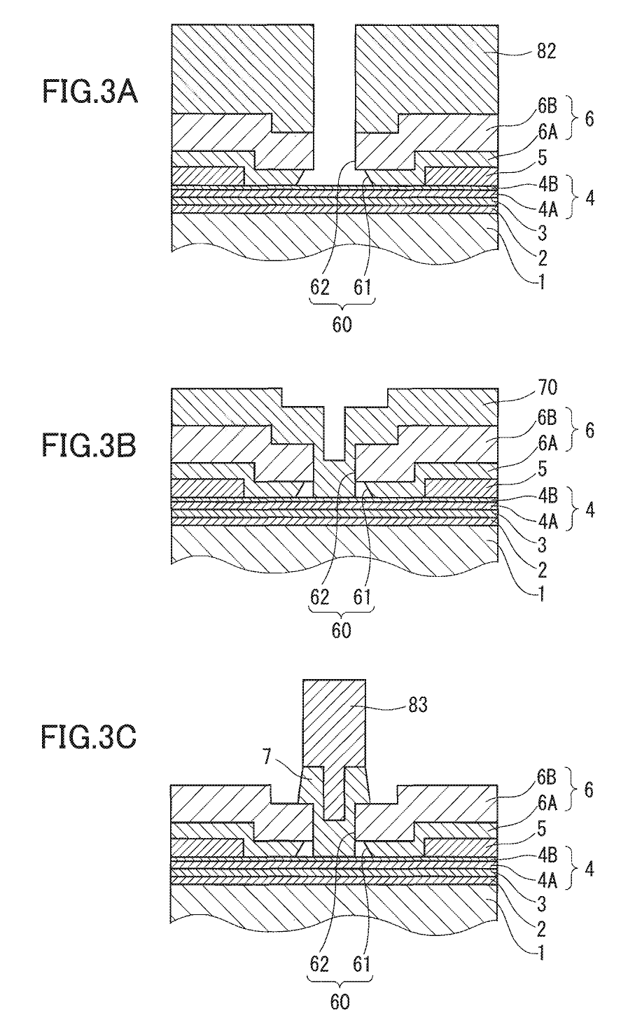

FIG. 1 is a cross-sectional view of a semiconductor device 10A according to a first embodiment of the present invention. FIGS. 2A to 2C and FIGS. 3A to 3C are diagrams for explaining a method of manufacturing the semiconductor device 10A shown in FIG. 1. The semiconductor device 10A of the present embodiment is a PHEMT, and includes a gate electrode 7, and a source electrode and a drain electrode disposed on opposite sides of the gate electrode 7. It should be noted that the source electrode and the drain electrode are not shown in the diagrams.

Specifically, the semiconductor device 10A includes: a semi-insulating substrate 1; a buffer layer 2 formed on the semi-insulating substrate 1; a channel layer 3 formed on the buffer layer 2; an electron supply layer 4 formed on the channel layer 3; ohmic contact layers 5 each formed in a predetermined region on the electron supply layer 4; and an insulating film 6 formed on the electron supply layer 4 so as to cover the electron supply layer 4 and the ohmic contact layers 5. The insulating film 6 is provided with an opening 60 for exposing a portion of the electron supply layer 4 between the ohmic contact layers 5. The gate electrode 7 has a cross section of an approximately “T” shape extending from above the insulating film 6 to the electron supply layer 4 through the opening 60, and forms, at its end, a Schottky junction with the electron supply layer 4.

In the present embodiment, a GaAs substrate may be used as the semi-insulating substrate 1. Furthermore, a GaAs layer may be used as the buffer layer 2, and a high-purity GaAs layer may be used as the channel layer 3. The ohmic contact layers 5 are, for example, n⁺-type GaAs layers.

The electron supply layer 4 includes a first electron supply layer 4A disposed on the channel layer 3 and a second electron supply layer 4B disposed on the first electron supply layer 4A. The second electron supply layer 4B has a lower surface state density and a higher resistance to oxidation than the first electron supply layer 4A. In the present embodiment, an AlGaAs layer may be used as the first electron supply layer 4A, and an InGaP layer may be used as the second electron supply layer 4B. The gate electrode 7 forms a Schottky junction with the InGaP layer. It should be noted, however, that the present invention is not limited to this combination of the first electron supply layer 4A and the second electron supply layer 4B. Any combination may be selected suitably as long as the above-mentioned conditions are satisfied.

The insulating film 6 includes an SiN film 6A disposed on the electron supply layer 4 and the ohmic contact layers 5, and an SiO₂ film 6B disposed on the SiN film 6A. These SiN film 6A and the SiO₂ film 6B have inner peripheral portions 61 and 62 respectively that constitute the inner peripheral surface of the opening 60. The inner peripheral portion 62 of the SiO₂ film 6B is in contact with the gate electrode 7, and the inner peripheral portion 61 of the SiN film 6A is recessed radially outwardly from the inner peripheral portion 62 of the SiO₂ film 6B to avoid a contact with the gate electrode 7. That is, the lower portion, which is located on the side of the electron supply layer 4, of the inner peripheral surface of the opening 60 in the insulating film 6 is not in contact with the gate electrode 7.

More specifically, the inner peripheral portion 61 of the SiN film 6A has a tapered shape widening toward the electron supply layer 4. A distance between the gate electrode 7 and the edge of the inner peripheral portion 61 on the side of the SiO₂ film 6B, that is, a distance between the gate electrode 7 and the inner peripheral portion 61 along the back surface of the SiO₂ film 6B, is preferably 10 nm or more. A distance between the gate electrode 7 and the edge of the inner peripheral portion 61 on the side of the electron supply layer 4, that is, a distance between the gate electrode 7 and the inner peripheral portion 61 along the front surface of the second electron supply layer 4B, is preferably 50 nm or less.

Any other material may be used to form the gate electrode 7 as long as it can form a Schottky junction with InGaP, but it is desirable to select high melting point materials such as WSi, WSiN, Mo, Ta, and TaN, which are thermally stable with respect to InGaP. Since the above high melting point materials have high metal resistance, it is desirable to form a film of a low resistance material, such as Al, an Al alloy such as Al and Si, Al and Cu, and Al and Ti, and Au, on a film of such a high resistance material to reduce the wiring resistance. Furthermore, when a high melting point metal and a low resistance metal are laminated to each other, it is desirable to insert a Ti film between them in order to enhance the adhesion therebetween.

Next, a method of manufacturing the semiconductor device 10A shown in FIG. 1 will be described with reference to FIGS. 2A to 2C and FIGS. 3A to 3C.

First, as shown in FIG. 2A, the buffer layer 2 and the channel layer 3 are stacked in this order on the semi-insulating substrate 1. Next, the electron supply layer 4 is formed by stacking the first electron supply layer (AlGaAs layer) 4A having a thickness of, for example, 20 nm and the second electron supply layer (InGaP layer) 4B having a thickness of, for example, 5 nm in this order on the channel layer 3. Furthermore, a primary ohmic contact layer 50 is formed on the electron supply layer 4.

Subsequently, as shown in FIG. 2B, a photoresist 81 is formed on the primary ohmic contact layer 50 and patterned to form the shape of the ohmic contact layers 5 so that they are etched to form an opening region. Then, by performing dry etching and wet etching, the ohmic contact layers 5 are formed and the second electron supply layer 4B of the electron supply layer 4 is exposed between the ohmic contact layers 50.

Next, as shown in FIG. 2C, the photoresist 81 is peeled off, and then the SiN film 6A having a thickness of, for example, 100 nm and the SiO₂ film 6B having a thickness of, for example, 300 nm are stacked in this order evenly on the second electron supply layer 4B and the ohmic contact layers 5 by P-CVD, and thereby the insulating film 6 is formed.

Subsequently, as shown in FIG. 3A, a patterned photoresist 82 is formed to define an opening region, for example, with a diameter of 0.4 μm. Dry etching may be performed using a mixed gas of CHF₃ and SF₆, and thereby the opening 60 is formed in the insulating film 6, so that the second electron supply layer 4B of the electron supply layer 4 is exposed through the opening 60. When the dry etching is performed as described above, the etching rate of the SiN film 6A is significantly higher than that of the SiO₂ film 6B. Therefore, only the SiN film 6A is susceptible to side-etching when the over-etching is performed. Accordingly, by controlling the gas ratio between CHF₃ and SF₆ so that the etching is performed under the etching gas conditions with a low deposition property, in which SiN is etched with a higher selectivity and at a higher rate than InGaP, the SiN film 6A can be side-etched by about 10 to 50 nm, while the second electron supply layer 4B hardly is etched. Thereby, the inner peripheral portion 61 of the SiN film 6A can be recessed outwardly from the inner peripheral portion 62 of the SiO₂ film 6B.

Next, as shown in FIG. 3B, the photoresist 82 is peeled off, and the gate electrode material is deposited evenly on the insulating film 6 to form a metal film 70. Thereby, the metal film 70 forms a Schottky junction with the second electron supply layer 4B through the opening 60 of the insulating film 6. Here, the metal film 70 is formed by a normal evaporation method, or a sputtering technique such as a long-throw sputtering method and a collimate sputtering method exhibiting excellent performance in the deposition in the normal line direction. By forming the metal film 70 using any of such methods exhibiting good performance in the normal deposition, the gate electrode material does not adhere to the side-etched SiN film 6A, and thus a gap of 10 to 50 nm can be formed between the gate electrode material and the inner peripheral portion 61 of the SiN film 6A.

Next, as shown in FIG. 3C, a patterned photoresist 83 is formed on the metal film 70 to define an intended region thereon, and then a portion of the metal film 70 deposited outside the periphery of the opening 60 on the insulating film 6 is removed by dry etching. Thus, the T-type gate electrode 7 can be formed.

Finally, the photoresist 83 is peeled off, and thereby the semiconductor device 10A as shown in FIG. 1 can be obtained.

The use of the above-mentioned method makes it possible to manufacture, with high consistency, the semiconductor device 10A having a low leakage current and excellent high frequency response characteristics, and capable of high-speed operation. Specifically, in the semiconductor device 10A manufactured as described above, the gate electrode 7 is not in contact with the inner peripheral portion 61, that is, the lower portion located on the side of the electron supply layer 4, of the opening 60 in the insulating film 6. Therefore, a concentration of strain can be alleviated, and thus a leakage current can be suppressed. In addition, the semiconductor device 10A, in which the AlGaAs layer as the first electron supply layer 4A is covered with the InGaP layer as the second electron supply layer 4B, is excellent in high-frequency response characteristics. Furthermore, since the gate length can be reduced (to 0.4 μm in the present embodiment) by dry etching, the semiconductor device 10A can operate at high speed. Still furthermore, since the insulating film 6 located between the head portion of the T-type gate electrode 7 and the second electron supply layer 4B has a multilayer structure including the SiN film 6A and the SiO₂ film 6B, it has a low dielectric constant and thus a loss in the capacitance can be reduced.

It should be noted that the thickness of the AlGaAs layer is 20 nm in the present embodiment, but it may be changed depending on the intended use. The diameter of the opening 60 in the insulating film 6 is 0.4 μm in the present embodiment, but any other diameter may be used as long as it is 0.5 μm or less. Furthermore, the width of the side etching of the SiN film 6A is 10 to 50 nm in the present embodiment, but there is no particular limitation on the width of the side etching as long as the inner peripheral portion 61 does not reach the ohmic contact layers 5.

### Second Embodiment

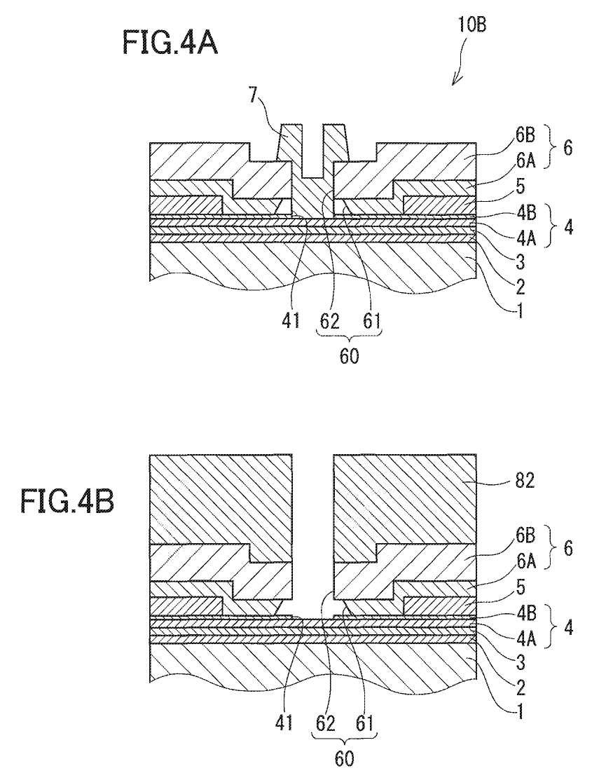

FIG. 4A is a cross-sectional view of a semiconductor device 10B according to a second embodiment of the present invention. In the second embodiment and the third embodiment to be described later, the same components as those in the first embodiment are designated by the same reference numerals and no further description is given.

In the semiconductor device 10B, the AlGaAs layer as the first electron supply layer 4A serves as a Schottky layer that forms a Schottky junction with the gate electrode 7, and the InGaP layer as the second electron supply layer 4B is a surface layer that is adjacent to the gate electrode 7. Specifically, the second electron supply layer 4B has an opening 41 having a shape obtained by projecting the shape of the inner peripheral portion 62, which is located on the side opposite to the electron supply layer 4, of the opening 60 in the insulating film 6, on the projected position in the second electron supply layer 4B. The first electron supply layer 4A is exposed through the opening 41. The gate electrode 7 forms a Schottky junction with the first electron supply layer 4A through the opening 41. This semiconductor device 10B is manufactured in the following manner.

First, the insulating film 6 is formed and then the opening 60 is formed in the insulating film 6 by dry etching in the same manner as in the first embodiment. Next, the etching gas is changed or the gas ratio between CHF₃ and SF₆ is changed, and the InGaP layer as the second electron supply layer 4B is etched anisotropically to form the opening 41, as shown in FIG. 4B. Thus, the AlGaAs layer as the first electron supply layer 4A is exposed. Subsequently, the metal film is formed and is subjected to microfabrication to form the gate electrode 7 in the same manner as in the first embodiment. Thus, the semiconductor 10B as shown in FIG. 4A can be obtained.

### Third Embodiment

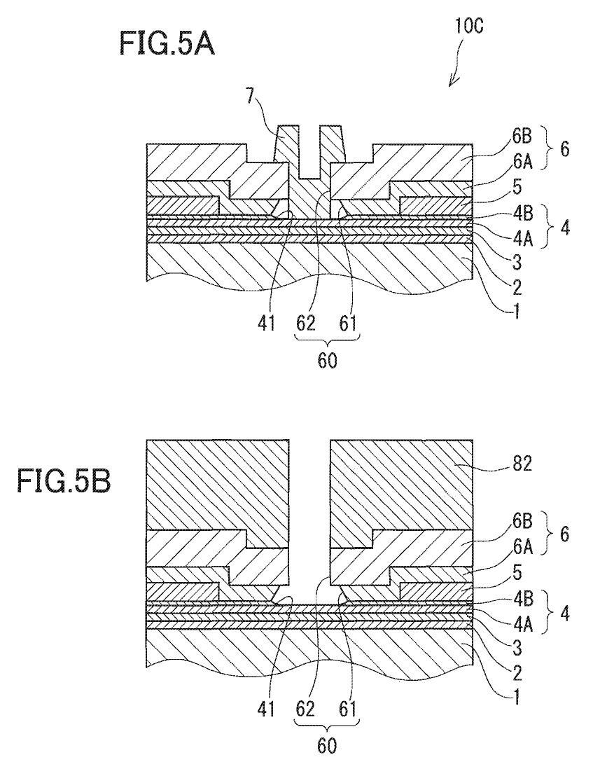

FIG. 5A is a cross-sectional view of a semiconductor device 10C according to a third embodiment of the present invention. In the semiconductor device 10C, as with the second embodiment, the AlGaAs layer as the first electron supply layer 4A serves as a Schottky layer that forms a Schottky junction with the gate electrode 7. It should be noted, however, that, in the third embodiment, the InGaP layer as the second electron supply layer 4B is a surface layer that is in slight contact with the gate electrode 7. Specifically, in the third embodiment, the opening 41 in the second electron supply layer 4B for exposing the first electron supply layer 4A has a crater shape with its inner peripheral surface being narrowed toward the first electron supply layer 4A. This semiconductor device 10C is manufactured in the following manner.

First, the insulating film 6 is formed and then the opening 60 is formed in the insulating film 6 by dry etching in the same manner as in the first embodiment. Next, the InGaP layer as the second electron supply layer 4B is etched isotropically by wet etching with hydrochloric acid to form the opening 41, as shown in FIG. 5B. Thus, the AlGaAs layer as the first electron supply layer 4A is exposed. Subsequently, the metal film is formed and is subjected to microfabrication to form the gate electrode 7 in the same manner as in the first embodiment. Thus, the semiconductor device 10C as shown in FIG. 5A can be obtained.

### Modification

In each of the above-mentioned embodiments, the channel layer 3 is formed on the semi-insulating substrate 1 via the buffer layer 2, but the channel layer 3 can be formed directly on the semi-insulating substrate 1 without the buffer layer 2.

The semi-insulating substrate 1 is not limited to the GaAs substrate, and any other substrates such as a GaN substrate may be used instead. In this case, the channel layer 3 and the first and second electron supply layers 4A and 4B may be changed depending on the material of the semi-insulating substrate 1.

The invention may be embodied in other forms without departing from the spirit or essential characteristics thereof. The embodiments disclosed in this specification are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device comprising:
a channel layer formed on a semi-insulating substrate;
an electron supply layer formed on the channel layer;
an insulating film formed on the electron supply layer and having an opening for exposing the electron supply layer; and
a gate electrode extending from above the insulating film to the electron supply layer through the opening, and forming, at its end, a Schottky junction with the electron supply layer,
wherein the electron supply layer includes: a first electron supply layer disposed on the channel layer; and a second electron supply layer disposed on the first electron supply layer and having a lower surface state density and a higher resistance to oxidation than the first electron supply layer,
the insulating film includes: an SiN film disposed on the electron supply layer; and an SiO₂ film disposed on the SiN film, and the SiN film and the SiO₂ film respectively have inner peripheral portions that constitute an inner peripheral surface of the opening, and
the inner peripheral portion of the SiO₂ film is in contact with the gate electrode, and the inner peripheral portion of the SiN film is recessed from the inner peripheral portion of the SiO₂ film to avoid a contact with the gate electrode.

2. The semiconductor device according to claim 1, wherein the first electron supply layer is an AlGaAs layer, and the second electron supply layer is an InGaP layer.

3. The semiconductor device according to claim 2, wherein the gate electrode forms a Schottky junction with the InGaP layer.

4. The semiconductor device according to claim 2, wherein the gate electrode forms a Schottky junction with the AlGaAs layer.

5. A method of manufacturing a semiconductor device, comprising:
a first step of forming a channel layer on a semi-insulating substrate;
a second step of forming an electron supply layer on the channel layer by stacking a first electron supply layer and a second electron supply layer in this order on the channel layer, the second electron supply layer having a lower surface state density and a higher resistance to oxidation than the first electron supply layer;
a third step of forming an insulating film on the electron supply layer by stacking an SiN film and an SiO₂ film in this order on the electron supply layer;
a fourth step of forming, in the insulating film, an opening for exposing the electron supply layer by dry etching;
a fifth step of forming, through the opening, a Schottky junction between the electron supply layer and a metal film by depositing the metal film from above the insulating film to form a gate electrode; and
a sixth step of forming the gate electrode by removing a portion of the metal film deposited outside the periphery of the opening on the insulating film.

6. The method of manufacturing a semiconductor device according to claim 5, wherein, in the fourth step, the dry etching is performed using a mixed gas of CHF₃ and SF₆ as an etching gas.
